(19) United States
(12) Patent Application Publication
(10) Pub. No.: US 2011/0074444 A1
(43) Pub. Date: Mar. 31, 2011

(54) SENSOR FOR DETECTION OF CONDUCTIVE BODIES

(75) Inventors: Jarkko Mäkiranta, Siuro (FI); Laurentiu Barna, Tampere (FI); Kari Kymäläinen, Tampere (FI); Mikko Martikainen, Tampere (FI)

(73) Assignee: MARIMILS OY, Vantaa (FI)

(21) Appl. No.: 12/993,019

(22) PCT Filed: May 13, 2009
(86) PCT No.: PCT/FI2009/050396

§ 371 Date: Nov. 16, 2010

(30) Foreign Application Priority Data
May 16, 2008 (FI) 20085461

(51) Int. Cl. G01R 27/26

(52) U.S. Cl. 324/663

(57) ABSTRACT

A sensor (100) for capacitively detecting presence of conductive objects (BOD1) comprises a first signal electrode (10a), a second signal electrode (10b), and a base electrode structure (20), wherein the distance (s3) between said first signal electrode (10a) and said second signal electrode (10b) is smaller than or equal to 0.2 times the width (s1) of said first signal electrode (10a), and wherein at least a part of said base electrode structure (20) is between said first signal electrode (10a) and said second signal electrode (10).

The present invention relates to capacitive detection of conductive bodies or targets, e.g. human beings.

### BACKGROUND

Presence of bodies or objects may be detected by determining a change of capacitance between two plates. The presence of an object causes a change in the dielectric constant between the plates, which causes a change in the capacitance formed by said two plates.

A capacitive sensor may be used e.g. to detect movements of people e.g. in an anti-theft alarm system.

### SUMMARY

An object of the present invention is to provide a sensor, a system, and a method for detection of conductive bodies.

The sensor comprises at least a first signal electrode, a second signal electrode, and a base electrode, which have been disposed in or on an electrically insulating substantially planar substrate. The base electrode is between the signal electrodes, wherein the distance between the first signal electrode and the second signal electrode is smaller than or equal to 20% of the width of the signal electrodes.

The sensor according to the invention may provide improved sensitivity when compared to a conventional sensor where the width of the signal electrode is substantially equal to the width of a ground electrode or when difference in the widths of the electrodes is smaller than according to the present invention.

The sensor according to the invention may detect the presence of conductive bodies which are farther away from the sensor than in case of conventional sensor where the width of the signal electrode is substantially equal to the width of a ground electrode. The sensor according to the invention has an extended reading distance for conductive objects.

The sensor according to the invention may be substantially insensitive to the alignment of the detectable body. The inactive area between the signal electrodes is small, and consequently it is virtually impossible to e.g. step on said inactive area. Blind spots may be avoided. The orientation of e.g. a foot of a person does not have a significant effect on the detectability.

The embodiments of the invention and their benefits will become more apparent to a person skilled in the art through the description and examples given herein below, and also through the appended claims.

### BRIEF DESCRIPTION OF THE DRAWINGS

In the following examples, the embodiments of the invention will be described in more detail with reference to the appended drawings, in which

FIG. 1 shows a sensor in a three dimensional view,

FIG. 2 shows, in a three dimensional view, a person stepping on a sensor,

FIG. 3 shows, in a side view, a person's foot positioned over a signal electrode,

FIG. 4 shows, in a side view, a person's foot positioned over a signal and a base electrode,

FIG. 5 shows, in a side view, a person's foot positioned over a sensor according to prior art,

FIG. 6 shows an equivalent circuit of a system comprising a sensor and a body,

FIG. 7a shows an equivalent circuit of a sensor without the presence of a body,

FIG. 7b shows an equivalent circuit of a system comprising a sensor, a body, and ground,

FIG. 8a shows an equivalent circuit of a system comprising a sensor and a cover layer disposed over the sensor,

FIG. 8b shows an equivalent circuit of a system comprising a sensor, a body, and a cover layer between the sensor and the body.

FIG. 9a shows signal and base electrodes disposed over a substrate,

FIG. 9b shows signal and base electrodes disposed under a substrate,

FIG. 9c shows signal and base electrodes between two substrates,

FIG. 9d shows signal and base electrodes disposed on different sides of a substrate,

FIG. 10 shows a sensor comprising an array of substantially rectangular signal electrodes having a base electrode structure between them,

FIG. 11 shows a sensor comprising an array of signal electrode groups, wherein each group comprises several signal electrodes connected in series,

FIG. 12 shows a base electrode structure which surrounds signal electrodes only partially.

FIG. 13a shows a sensor comprising an array of triangular signal electrodes,

FIG. 13b shows a sensor comprising an array of hexagonal signal electrodes,

FIG. 13c shows a sensor an array of square signal electrodes having rounded corners, and star-shaped base electrode areas in the vicinity of the corners of the signal electrodes,

FIG. 14a shows a web comprising signal and base electrode structures,

FIG. 14b shows a sensor provided by cutting the web of FIG. 14a,

FIG. 15 shows a measuring system comprising an array of signal electrodes and multiplexing unit,

FIG. 16 shows a measuring system comprising an array of signal electrodes and an array of monitoring units, and

FIG. 17 shows a sensor comprising an array of substantially circular signal electrodes,

All drawings are schematic.

### DETAILED DESCRIPTION

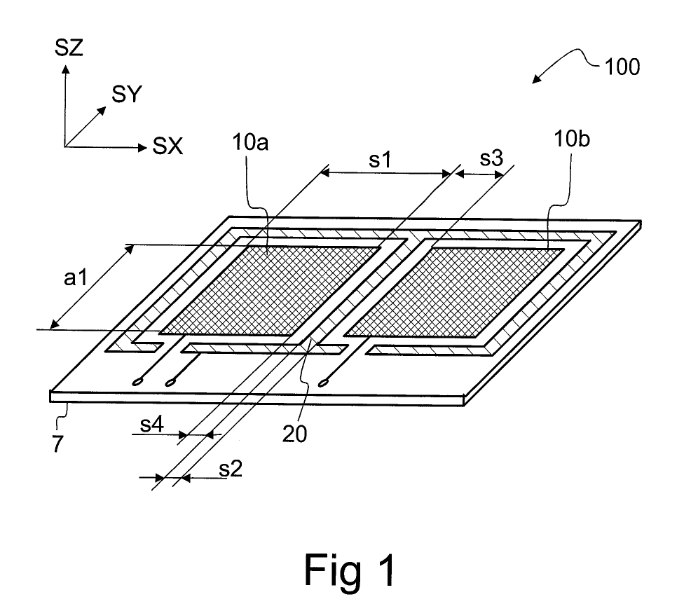

Referring to FIG. 1, a capacitive sensor 100 comprises a first signal electrode 10a, a second signal electrode 10b, and a base electrode structure 20 between said signal electrodes 10a, 10b. The base electrode structure 20 is herein called as a base electrode 20.

The electrodes 10a, 10b, 20 have been implemented in or on an electrically insulating substantially planar substrate 7. The sensor 100 may comprise e.g. metal foils 10a, 10b, 20 attached to a plastic foil 7. The sensor 100 may be flexible to facilitate transportation and storage in rolls. The thickness of the sensor (in direction SZ) may be smaller than or equal to 1 mm.

SX, SY and SZ denote three orthogonal directions. The directions SZ and SY define the plane of the substrate 7.

a1 denotes the height of the signal electrode 10a (in direction SY). s1 denotes the width of the signal electrode 10a (in direction SX). s3 denotes the distance between the first signal electrode 10a and the second signal electrode 10b. s2 denotes the width of that part of the base electrode 20 which is between the signal electrodes 10a, 10b. s4 denotes the width of a gap between the signal electrode 10a and the base electrode 20.

The distance s3 between the first signal electrode 10a and the second signal electrode 10b may be e.g. in the range of 5 to 30 mm.

The width s2 may be e.g. in the range of 0.3 to 15 mm, advantageously in the range of 1 to 7 mm, preferably in the range of 2 to 7 mm. The width s4 may be e.g. in the range of 0.3 to 15 mm, advantageously in the range of 1 to 7 mm.

The widths s2 and s4 may be substantially equal.

The surface area of the second signal electrode 10b may be in the range of 70% to 150% of the surface area of the first signal electrode 10b.

The surface area of the first signal electrode may be in the range of 0.02 to 0.2 m² to match e.g. with size of a foot of a person.

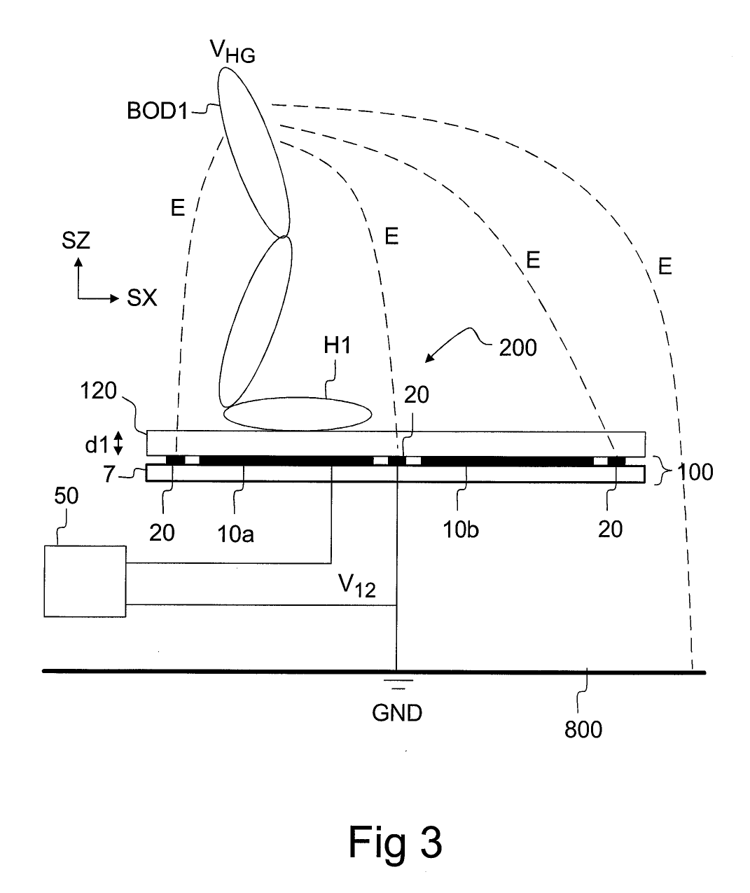

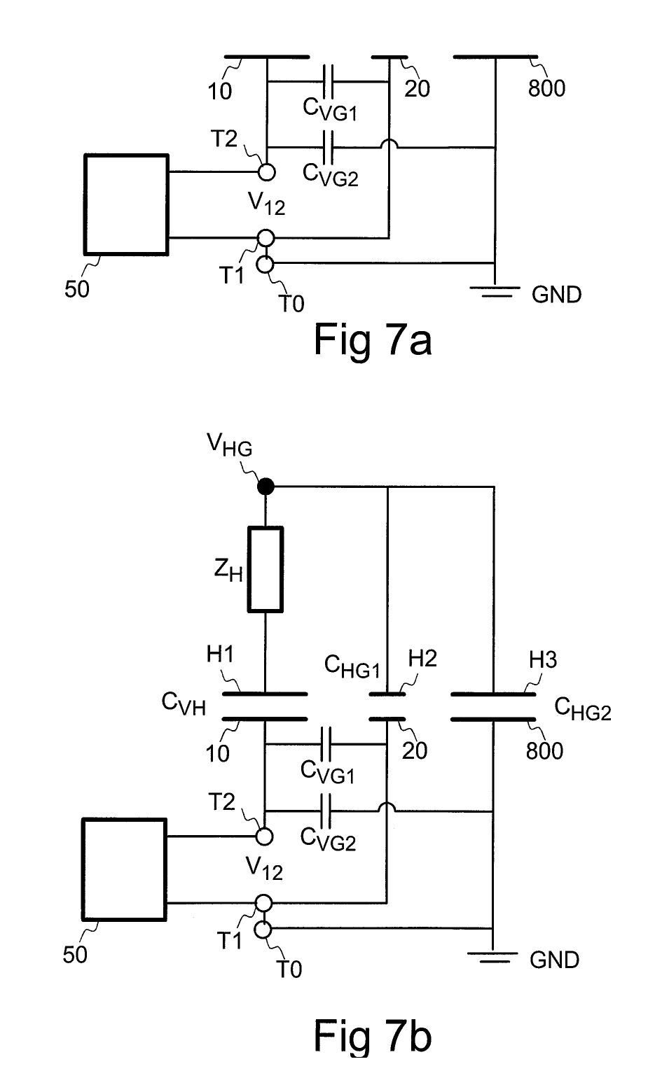

The presence of a body in the vicinity of the sensor is detected by monitoring a change in the capacitance of the first signal electrode 10a and the base electrode 20 by a monitoring unit 50 (see FIGS. 3 and 7b).

The presence of a body is detected by varying the voltage of a signal electrode with respect to the base electrode, and by determining a value which depends on the current of said signal electrode caused by said voltage variations. For example, a signal electrode may be charged to a predetermined voltage value, and discharged via a resistor to the base electrode. The presence of an object may be detected based on the time constant of the voltage decay. The voltage all signal electrodes may be varied with a substantially similar waveform.

The base electrode 20 acts as a counter-electrode for capacitive measurement. In addition, the base electrode 20 acts as a noise shield, i.e. as a Faraday cage.

In addition, also a change in the capacitance of the second signal electrode 10a and the base electrode 20 may be detected by a monitoring unit 50.

Base electrodes 20, which at least partially surround each of the signal electrodes 10a, 10b individually, may be in contact with each other. Thus, a single base electrode structure 20 may surround the first 10a and the second 10b signal electrode.

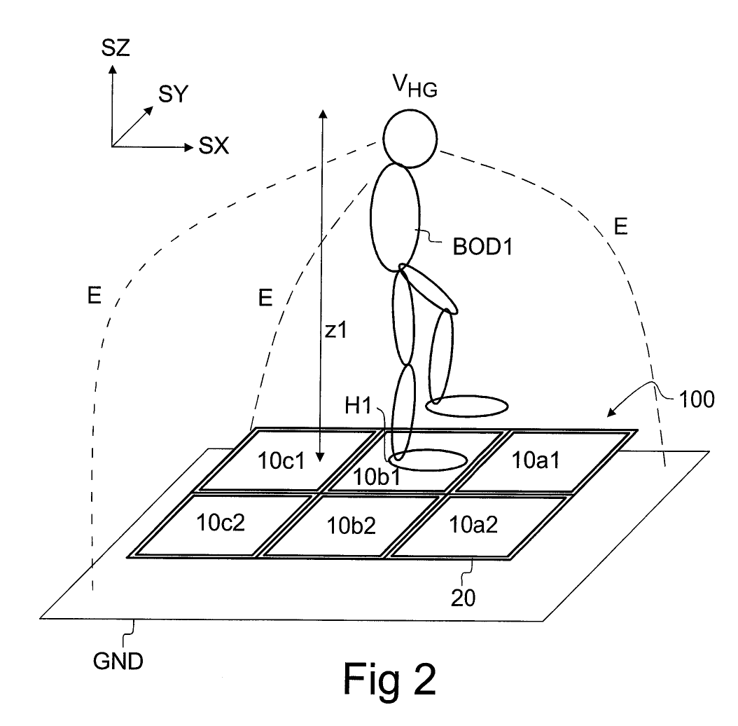

FIG. 2 shows a person walking over a sensor 100, which comprises several independent signal electrodes 10a1, 10a2, 10b1, 10b2, 10c1, 10c2, and one or more base electrodes 20.

The voltage of the signal electrode 10b1 is varied with respect to the base electrode 20 and the ground GND. The varying voltage of the signal electrode is capacitively coupled via the foot of the person to the body BOD1 of the person. The voltage is varied at such a frequency that the body BOD1 acts as an electrical conductor. Consequently, the whole body BOD1 of the person has a varying (e.g. alternating) voltage V_{HG} with respect to the base electrode 20 and the ground GND. This causes a varying electric field E between the body BOD1 and the base electrode 20, as well as between the body BOD1 and the ground GND. Thus, the person's body is effectively coupled as a part of a capacitive system formed by the electrodes 10b1, 20, and the ground GND.

The capacitance of each signal electrodes 10a1, 10a2, 10b1, 10b2, 10c1, 10c2 with respect to the base electrode may be monitored substantially independently. Thus, the location of the person may be effectively tracked.

For optimum spatial resolution, the area of an individual signal electrode may be in the range of 0.02 m2 to 0.2 m2, i.e. comparable to the bottom are of the foot H1.

There may be cover layer 120 between the sensor 100 and the body BOD1. The cover layer may be e.g. a carpet or a layer of epoxy coating. d1 denotes the thickness of the cover layer 120. The thickness d1 of the cover layer may be e.g. in the range of 2 to 10 mm.

FIG. 3 shows a side view of a person's foot stepping over a signal electrode 10a. A monitoring unit 50 varies the voltage V₁₂ of the signal electrode 10a with respect to the base electrode 20 and the ground GND.

The measuring system 200 comprises the sensor 100 and a monitoring unit 50.

The ground GND may also act as an electrode 800 having a very large area.

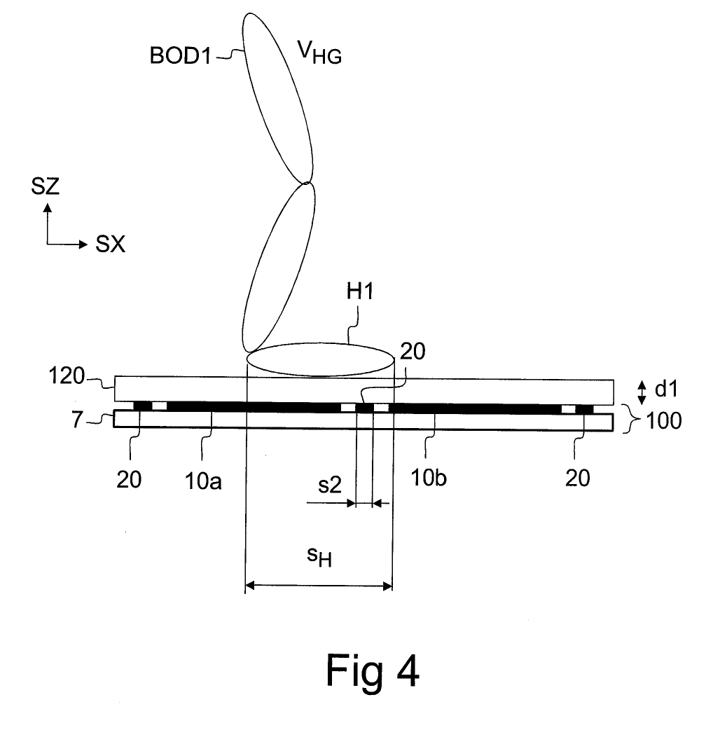

The width s1 of the signal electrodes 10a, 10b may be selected to be e.g. in the range of 0.5 to 2 times the length S_{H} (FIG. 4) of the foot H1. In order to provide optimum spatial resolution. The narrow distance s3 between the signal electrodes 10a, 10b makes it nearly impossible to step onto an inactive grounded area, where the presence of the person would not be detected.

The monitoring unit 50 provides a varying voltage V₁₂ at least to the electrodes 10a, 20, and it determines a value which depends on the current of said signal electrode caused by said voltage variations. The monitoring unit 50 may comprise a decision sub-unit (not shown) for generating a digital signal based on said value or based on the rate of change of said value. The digital signal may indicate the presence or absence of the body BOD1 in the vicinity of the electrode 10a.

The voltage V₁₂ coupled to the signal electrode 10a may vary at a frequency f1 which is e.g. in the range of 20 kHz to 1 MHz, advantageously in the range of 50 kHz to 300 kHz. The voltage V12 may have a complex waveform, and in that case at least 90% of the power of the spectral components of said varying voltage (V₁₂) may be within the frequency range of 20 kHz to 1 MHz, preferably within 50 kHz to 300 kHz

The use of a higher frequency f1 may lead to increased power consumption. The conductivity of e.g. human body may decreases at high frequencies. The signal-to-noise ratio may be low at a lower operating frequency f1. The frequency f1 may be selected so that the sensor 100 does not generate interference to other electric devices, e.g. to medical appliances.

FIG. 4 shows the foot H1 of the person stepping over the base electrode 20. The capacitance of a capacitor formed between the foot H1 and the base electrode is substantially smaller than the capacitance of a capacitor formed between the foot H1 and the signal electrode, because the width s2 of the base electrode 20 is substantially smaller than the width s1 of the signal electrode 10a (see FIG. 1). Consequently, the voltage V_{HG} coupled to body BOD1 may have nearly the same magnitude as the voltage V12 provided by the monitoring unit 50.

The second signal electrode 10b may be switched to a high-impedance floating state when the varying voltage V₁₂ is coupled to the first signal electrode 10a. Thus, the second signal electrode 10b does not capacitively short-circuit the voltage V_{HG} coupled to the body BOD1, and a coupled voltage V_{HG} may be high although the foot H1 is partially over the second signal electrode 10b, in addition to being over the first signal electrode 10a and over the base electrode 20.

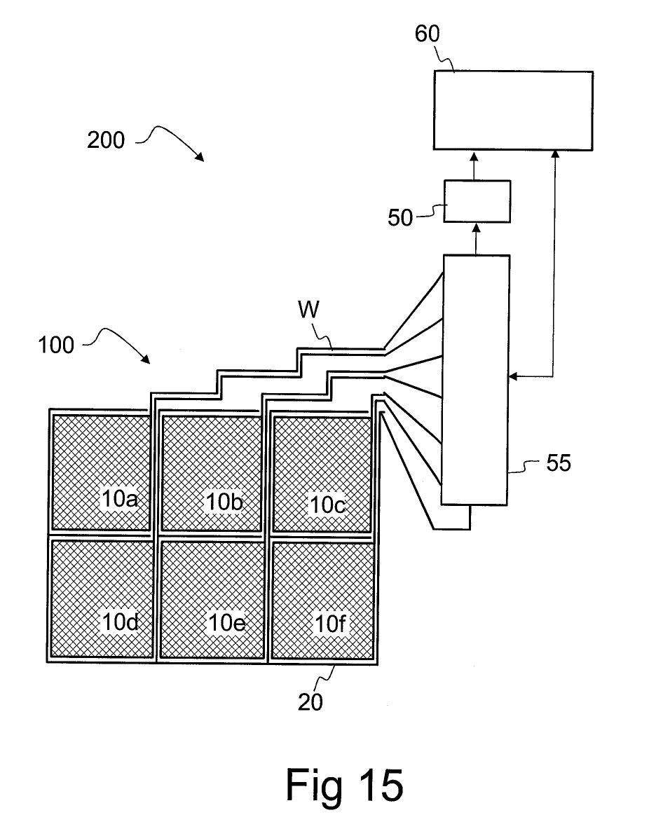

A single monitoring unit 50 may be connected to the first and to the second signal electrode by time-based multiplexing, by using a multiplexing unit 55 (FIG. 15). The multiplexing unit 55 may be arranged to disconnect the second signal electrode 10b from the monitoring unit 50 and to leave it in a high impedance state when the varying voltage V₁₂ is coupled to the first signal electrode 10a.

In particular, substantially all signal electrodes adjacent to the first signal electrode 10a, may be switched into the high impedance state when the detection is performed by using the first signal electrode 10a.

Alternatively, varying voltages V₁₂ may be simultaneously connected to the first signal electrode 10a and to the second signal electrode 10b. The varying voltages V₁₂ coupled to the first signal electrode 10a and to the second signal electrode 10b may be substantially in the same phase In order to provide a high coupled voltage V_{HG} also in a situation when the foot H1 is partially over the second signal electrode 10b, in addition to the first signal electrode 10a and the base electrode 20. However, the spatial resolution may be worse than when switching the second signal electrode into the high-impedance state.

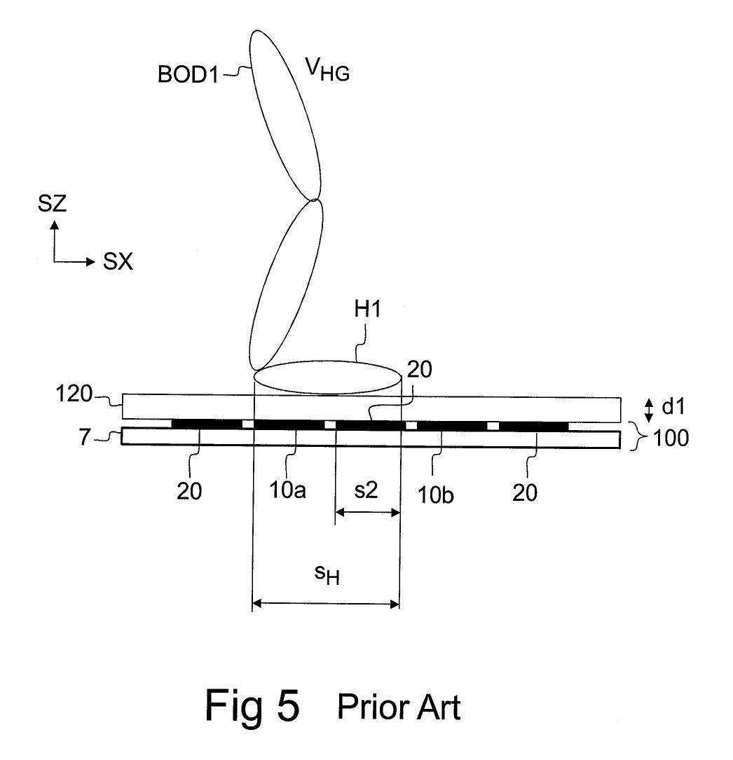

FIG. 5 shows a comparative example (Prior Art), where the width s2 of a base electrode 20 is substantially equal to the width of the signal electrode 10a. In that case the voltage V_{HG} coupled to the body BOD1 is nearly 50% lower than in case of FIGS. 3 and 4, because, and the capacitance between the foot H1 and the base electrode 20 is substantially equal to the capacitance between the foot H1 and the signal electrode 10a. The foot H1 is partially short circuited to the base electrode 20 due to the large area of the base electrode 20.

The voltage V_{HG} coupled to the body BOD1 in case of FIGS. 3 and 4 is approximately 50-100% higher than in case of FIG. 5. Thanks to the large signal electrode 10a, the body BOD1 is effectively coupled to it. Simulations and experimental measurements indicate a signal to noise ratio (S/N) which is increased by 50% to 100% when compared to the situation of FIG. 5. The improved signal to noise ratio enables a more sensitive measurement and/or a longer reading distance.

The sensor according to FIG. 5 does not utilize effectively the electrical conductivity of the body BOD1. It merely detects a change of permittivity caused by the presence of the foot H1. This leads to a limited detection performance when compared with the present invention.

The sensor 100 of FIGS. 3 and 4 according to the present invention is optimized for detecting the presence of conductive bodies BOD1 which substantially extend from the level of the substrate, e.g. upwards.

The sensor 100 according to FIGS. 3 and 4 take advantage of the electrical conductivity of the body BOD1, thus providing improved sensitivity when compared with the prior art solutions (FIG. 5). Almost the whole surface area of the body BOD1 is coupled act as a capacitive electrode (not the bottom area of the foot H1) which creates an electric field E together with the base electrode 20 and possibly also with the earth GND, 800.

The sensor 100 is optimized to detect the presence of large conductive objects. A conductive object may be considered to be a “large” if its vertical dimension z1 (in the direction SZ) is greater than the dimensional and the dimension s1 of the signal electrode 10a (FIG. 1).

The sensor 100 has a reduced sensitivity for smaller objects which are positioned at a low level. This is an advantage when the aim is e.g. to distinguish the presence of a human being from the presence of a smaller non-conductive object such as a wooden chair, for example.

For example, it was experimentally noticed that a glass of water positioned on the signal electrode 10a provided a rather low signal, wherein the signal level increased drastically when a person toughed the water in the glass with his finger.

For conventional sensors having signal and ground electrodes of equal size (FIG. 5), and having the gap width between said electrodes substantially equal to size of said electrodes, it has been noticed that the effective reading distance of such sensors is approximately only 1.33 times the gap between the electrodes. Thus, for the sensor 100 according to the present invention, the sensitivity for low objects may be reduced by selecting the gap width s4 between the signal electrode 10 and the base electrode 20 to be smaller than the thickness d1 of the cover layer 120. The gap width s4 advantageously smaller than 0.75 times the thickness d1 of the cover layer.

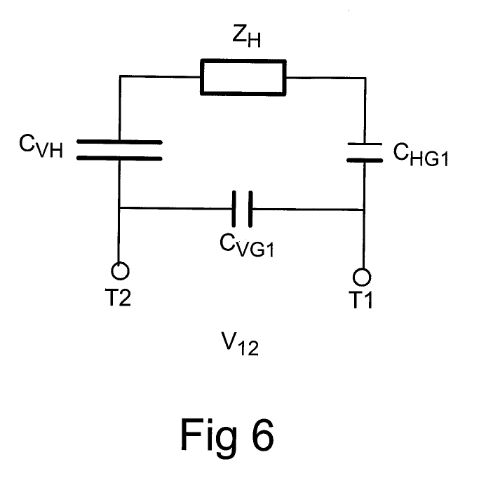

FIG. 6 shows a simplified equivalent circuit of system comprising a sensor 100 and a body BOD1. A varying voltage V₁₂ is coupled between terminals T1 and T2. The terminal T2 is coupled to a signal electrode 10 and the terminal T1 is coupled to a base electrode 20. The signal electrode 10 and the base electrode 20 form a capacitor C_{VG1} even when a body BOD1 is not present.

When a body BOD1 is positioned in the vicinity of the electrodes 10a, 20, an impedance Z_{H} formed by the body is capasitively coupled between the electrodes 10, 20. The body BOD1 and the signal electrode 10 form together a capacitor C_{VH}. The body BOD1 and the base electrode 20 form together a capacitor C_{HG1}.

FIG. 7a shows a more detailed equivalent circuit of a measuring system where the base electrode 20 is also connected via a terminal T0 to the ground GND. The ground GND forms an additional, very large capacitor plate 800. The signal electrode 10 and the ground GND form together a further capacitor C_{VG2}, even when a body BND is not present.

The base electrode may be connected to the ground, e.g. to the ground of the mains network in a building, to the metallic water pipelines of a building or to a special ground electrode buried into the soil. This helps to provide a very large electrode surface. Alternatively, or in addition to, the ground GND may also be established by those parts of the base electrode structure which are relatively far away from the body BOD1 or which are far away from the foot H1 of a person. The base electrode may be mesh structure which covers substantially the entire area of a room. Thus, it may represent a relatively large surface area.

The surface area of the base electrode structure 20 may be greater than or equal to the surface area of the first signal electrode 10a.

Referring to FIG. 7b, the surface of an electrically conductive body BOD1 has surfaces H1, H2 and H3, by which the impedance Z_{H} of the body BOD1 is capacitively coupled to the signal electrode 10, to the base electrode 20, and to the ground GND. The body BOD1 forms a capacitor C_{VH} together with the signal electrode 10. The body BOD1 forms a capacitor C_{HG1} together with those parts of the base electrode 20 which are in the vicinity of the body BOD1. The body BOD1 forms a capacitor C_{HG2} together with the ground GND, 800.

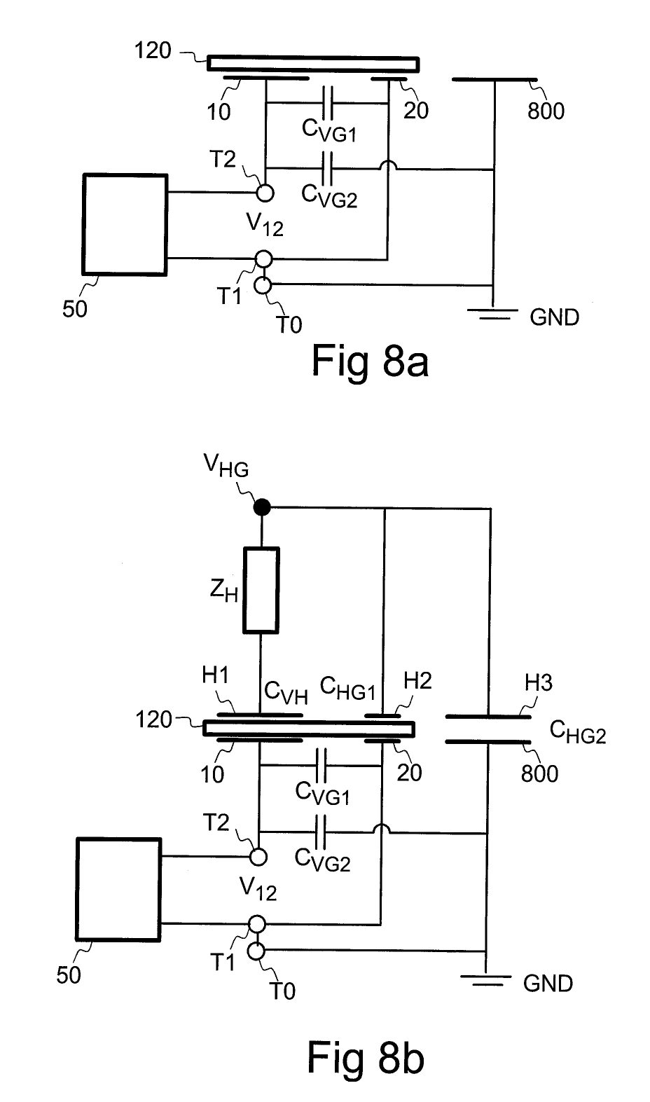

Referring to FIGS. 8a and 8b, a cover layer 120 may be positioned over the electrodes 10, 20. FIG. 8a shows the equivalent circuit without the presence of a body BOD1, and FIG. 8b shows the equivalent circuit with the impedance Z_{H} of the body. The dielectric permittivity of the cover layer 120 deviates from the permittivity of air. Thus, the capacitance of the capacitors C_{VG1}, C_{VH}, C_{HG1}, C_{HG2} is different from the values of FIGS. 8a and 8b.

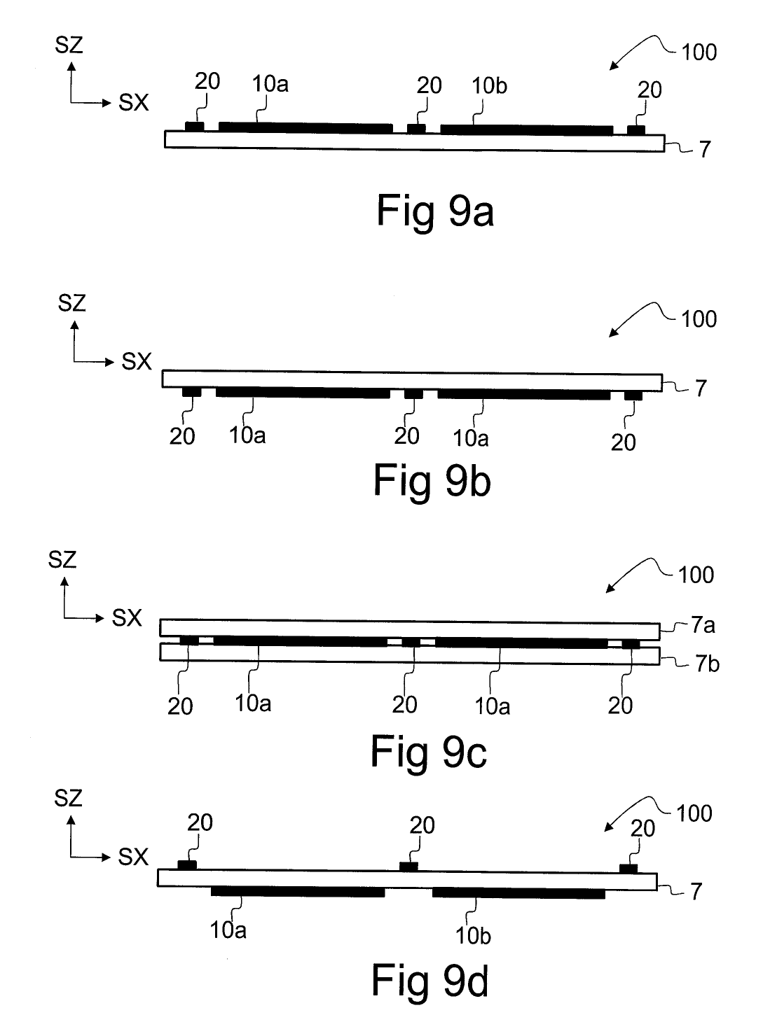

FIG. 9a shows a sensor wherein the signal electrodes 10a, 10b and the base electrode have been implemented on an electrically insulating substrate 7 substantially in the same plane.

FIG. 9b shows the sensor 100 of FIG. 9a upside down. Now the substrate 7 protects the electrodes from wear and prevents a galvanic contact between the electrodes and conductive bodies BOD1. However, the surface below the sensor 100 should be electrically insulating. The sensor 100 may be e.g. glued into a floor. In that case the glue and the floor should be electrically insulating.

FIG. 9c shows a sensor 100 where the signal electrodes 10a, 10b and the base electrode 20 have been implemented between two substrates 7a, 7b. In that case the electrodes 10a, 10b, 20 are well protected from both sides.

FIG. 9d shows a sensor where the signal electrodes 10a, 10b are at a different level than the base electrode 20. This may be more complex to manufacture than the examples shown in FIGS. 9a to 9c.

The upper and/or lower side of sensor 100 may be coated with an adhesive (not shown) in order to facilitate easier installation e.g. on a floor. E.g. a pressure sensitive adhesive (pressure-activated adhesive) may be used. The adhesive layer may be protected by a removable release layer (not shown). Installation is also possible by using normal gluing methods known in the art.

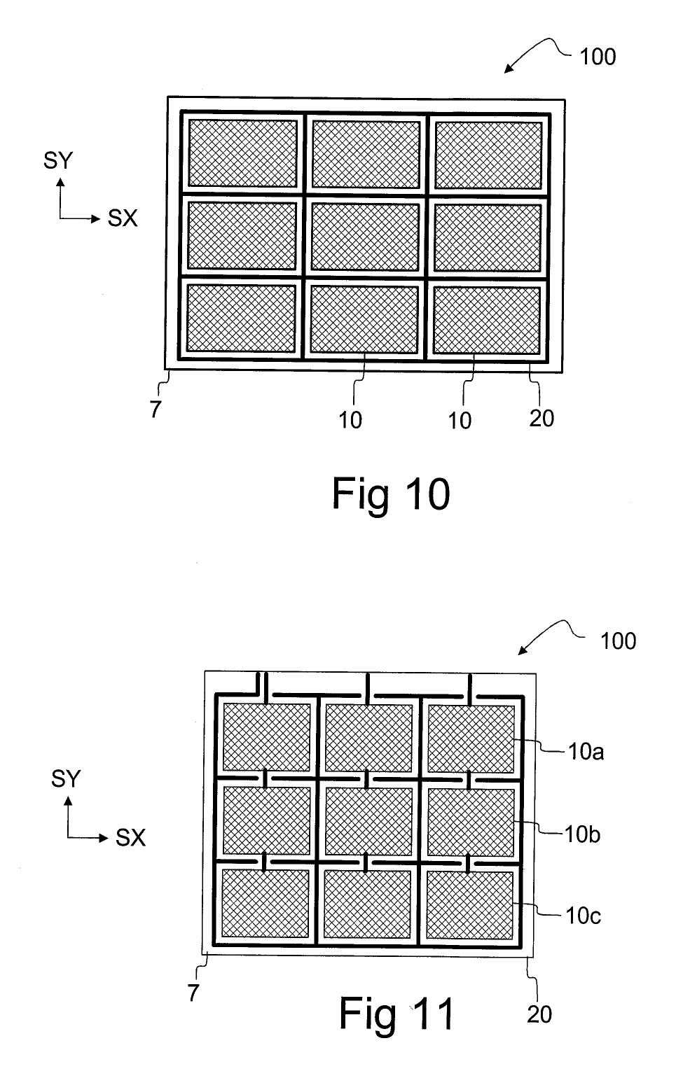

Referring to FIG. 10, the sensor 100 may comprise an array of substantially rectangular signal electrodes 10, which have at least one base electrode structure 20 between them.

Referring to FIG. 11, two or more signal electrodes may be coupled electrically in series and/or in parallel in order to increase an individually monitored area.

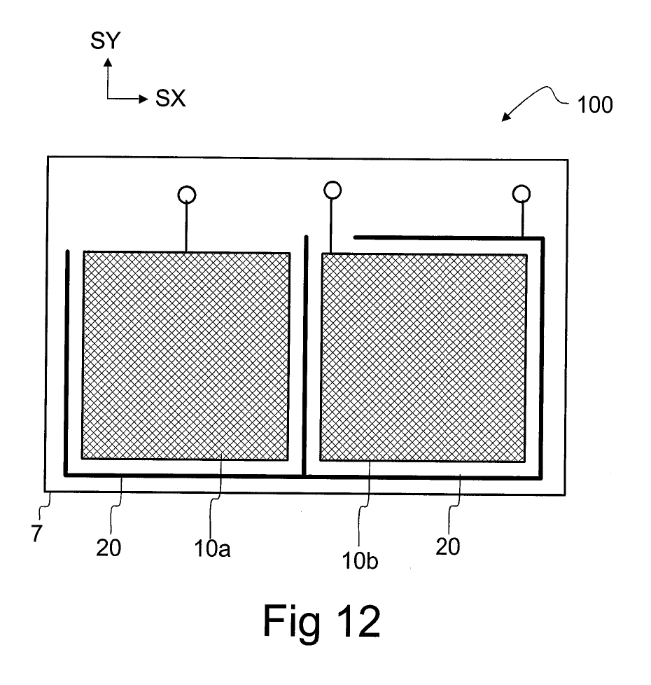

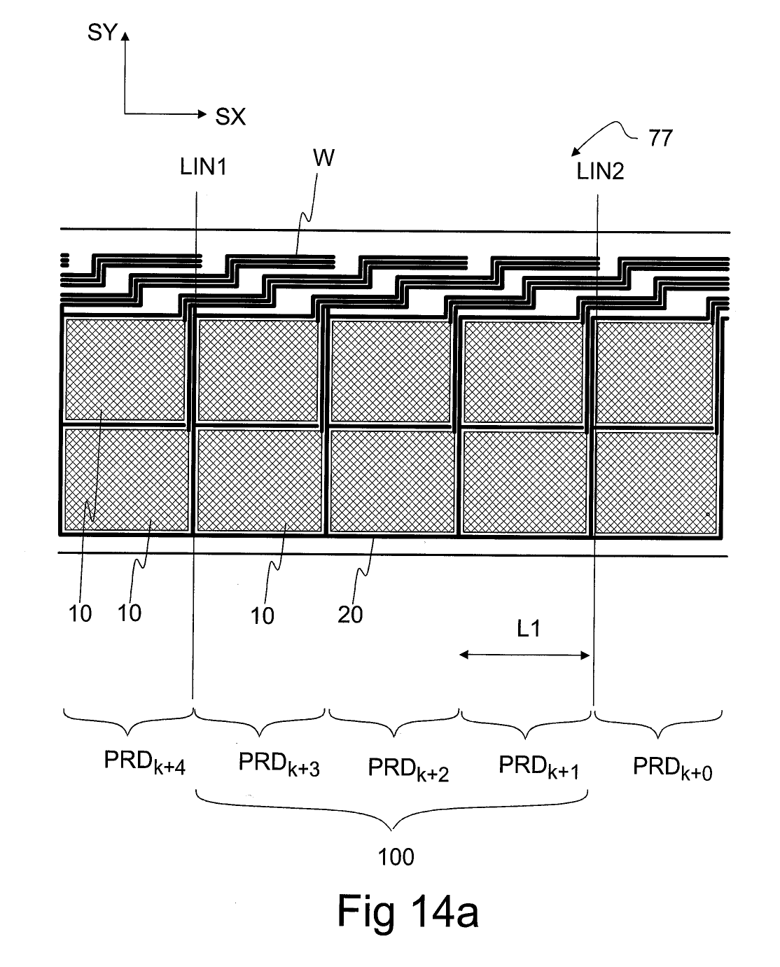

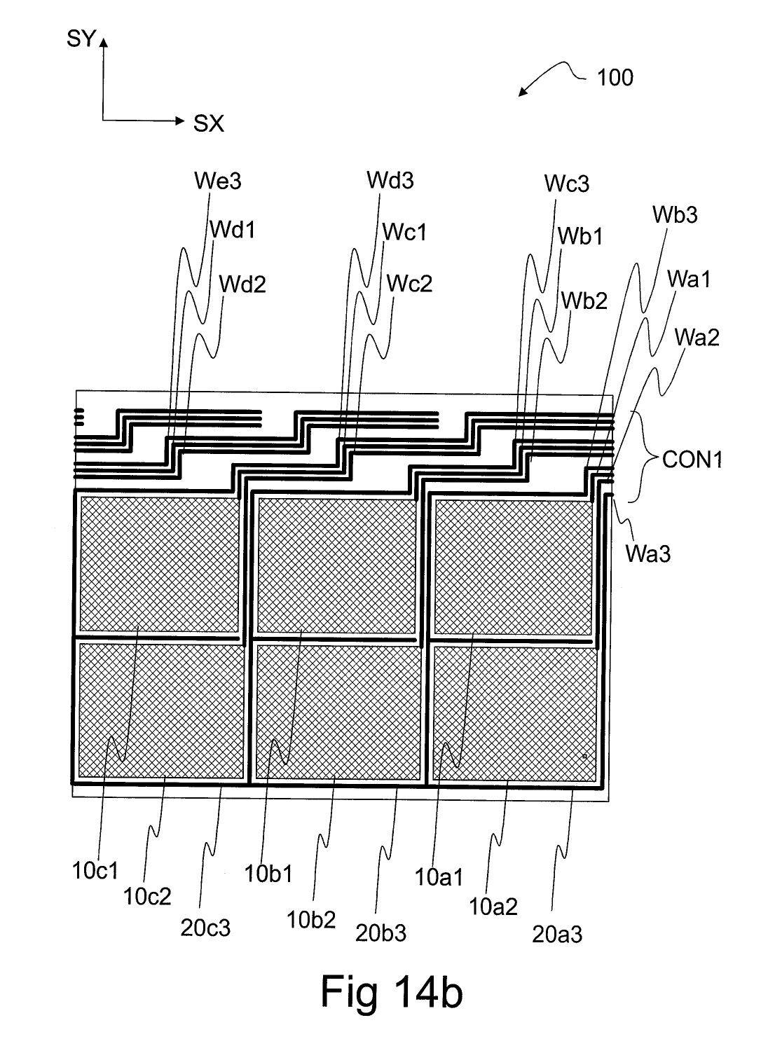

Referring to FIG. 12, at least 70% of the perimeter of a signal electrode 10a may be surrounded by the base electrode 20. Advantageously, at least 95% of the perimeter of the signal electrode 10b may be surrounded by the base electrode 20 as shown also in FIGS. 11 and 14b. The base electrode 20 may also completely surround the signal electrode, as shown e.g. in FIG. 10.

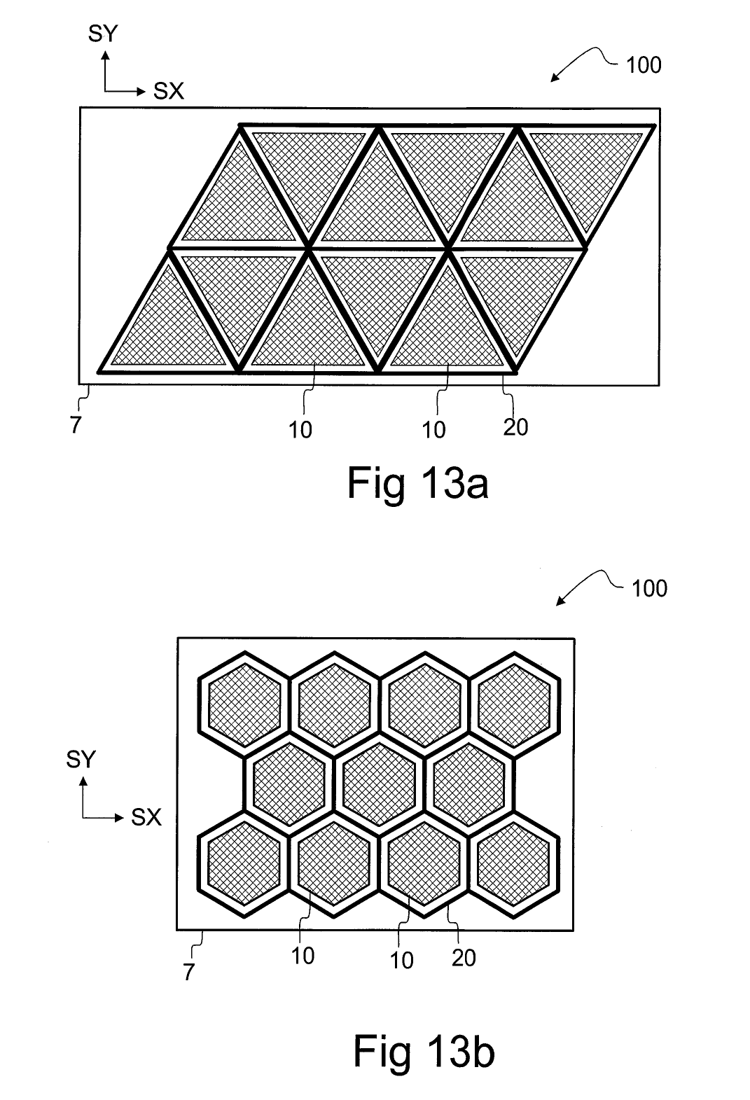

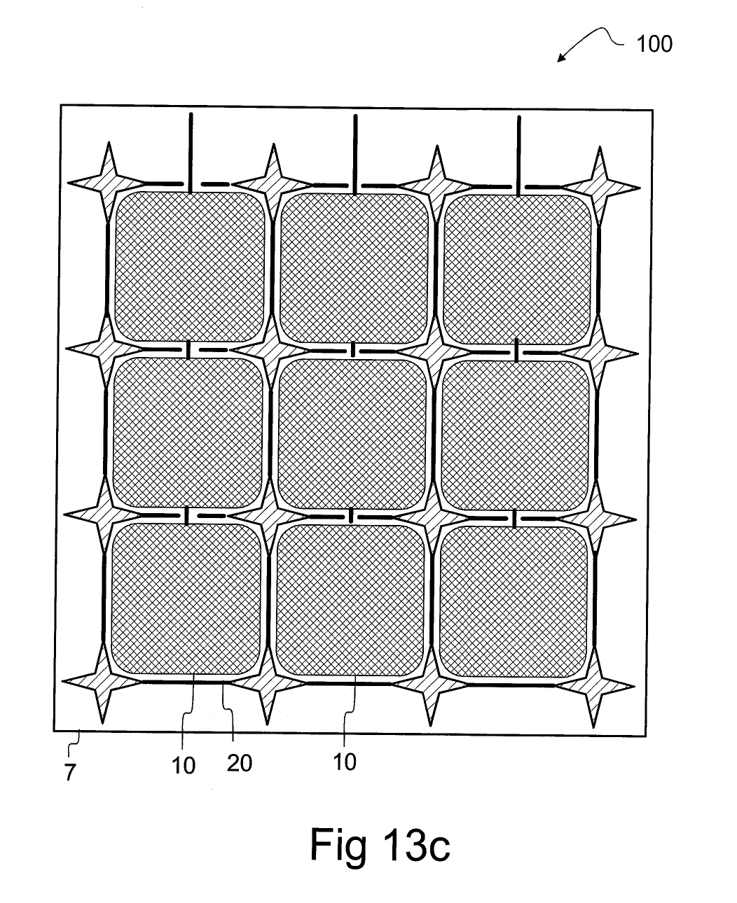

Referring to FIG. 13a, the sensor 100 may comprise a substantially triangular array of signal electrodes 10.

Referring to FIG. 13b, the sensor 100 may comprise a substantially hexagonal array of signal electrodes 10.

Referring to FIG. 13c, the sensor 100 may comprise e.g. rectangular signal electrodes 10 having rounded corners. The base electrode 20 may have star-shaped areas.

The sensors 100 of FIGS. 10, 13a or 13b may comprise electrical feedthroughs (vias) in order to couple connectors to the signal electrodes which are in the middle of the array. The sensors 100 of FIGS. 10, 13a or 13b may also be modified in a similar way as in FIG. 11 so as to implement the conductive parts in a single plane.

The signal electrodes 10 may also have other forms, e.g. octagonal or circular shape. Adjacent signal electrodes may have a different shape.

However, it is advantageous to select the shape(s) of the signal electrodes 10 such that the distance between adjacent signal electrodes is kept substantially at the predetermined value s3 (FIG. 1). Thus, the signal electrodes may have mutually matching contours.

Referring to FIG. 14a, a plurality of signal electrodes 10 and at least one base electrode structure 20 may be implemented on a sensor web 77, e.g. on a continuous band comprising electrode structures. A substantially similar electrode pattern may be periodically copied along the web in the direction SX, i.e. in the longitudinal direction of the web 77. The electrode pattern has a period, which has a length L1. Thus, the consecutive periods PRDₖ₊₀, PRDₖ₊₁, PRDₖ₊₂, PRDₖ₊₃, PRDₖ₊₄ have substantially the same electrode pattern and substantially the same length L1. In other words, the web 77 may exhibit periodicity.

The signal electrodes 10 of successive periods may be electrically isolated from each other. Each of the electrodes 10, 20 is connected to a conductor W. The conductors W of at least three periods may be arranged to cross a transverse line LIN2, wherein conductors from farther periods may be arranged to terminate without crossing the line LIN2.

The electrodes and the conductors are advantageously implemented in the same plane in order to simplify the manufacturing of the web 77.

The web 77 may manufactured e.g. by using a roll-to-roll process.

The sensor 100 shown in FIG. 14b may be obtained by cutting along the lines LIN1, LIN2 of the continuous web 77 of FIG. 14a. The conductors Wa1, Wa2, Wa3, Wb1, Wb2, Wb3, Wc1, Wc2, Wc3, and Wd3 terminate in the vicinity of the cut edge of the sensor 100. This facilitates coupling of a connector CON1 to said conductors, in order to individually monitor the presence of objects in the vicinity of the signal electrodes 10a1, 10a2, 10b1, 10b2, 10c1, 10c2. The base electrodes 20a3, 20b3 and 20c3 are shown to be connected together. However, they may also be galvanically separate.

The sensor comprises conductors Wd1, Wd2, We3, which terminate before reaching said cut edge. These conductors were connected to electrodes, which were cut away from the sensor 100, or which will be inactive.

Referring to FIG. 15, the measuring system 200 may comprise the sensor 100, a multiplexing unit 55, a monitoring unit 50, and a data processor 60. The multiplexing unit 55 may be arranged to couple each independent signal electrode 10a, 10b, 10c, 10d, 10f, 10e to the monitoring unit 50, each at a time. The multiplexing unit 55 may be arranged may be arranged to switch all other signal electrodes to the high impedance state.

The data processor 60 be arranged to provide information on the location of a body BOD1 based on signal or signals provided by said monitoring unit. The system 200 may provide information on the movement of the body BOD1 based on said signal or signals.

The data processor 60 may also communicate with the multiplexing unit 55 so as to control the order and/or the rate in which the varying voltage V₁₂ is coupled to the different signal electrodes. The multiplexing unit 55 may be arranged to send a synchronization signal and/or information regarding the identity of the electrode(s) which are activated at a given time.

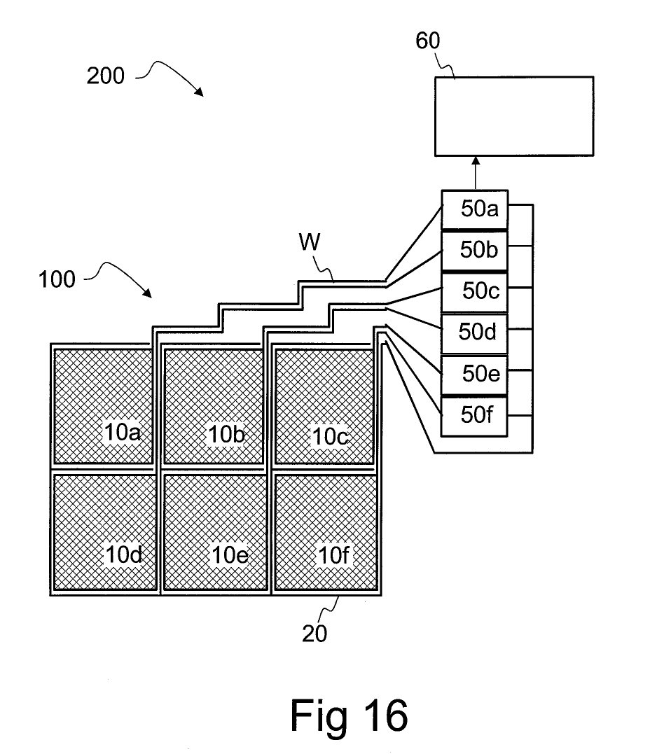

Referring to FIG. 16, the measuring system 200 may comprise the sensor 100, one or more measuring units 50a, 50b, 50c, 50d, 50e, 50f, and a data processor 60. Each independent signal electrode 10a, 10b, 10c, 10d, 10f, 10e may be connected to a respective monitoring unit.

The, the system 200 may comprise an array of monitoring units 50a, 50b, 50c, 50d, 50e, 50f coupled to an array of signal electrodes 10a, 10b, 10c, 10d, 10e, 10f, and a data processor 60 arranged to provide information on the location of a body BOD1 based on a plurality of signals provided by said monitoring units. The system 200 may provide information on the movement of the body BOD1 based on said signals.

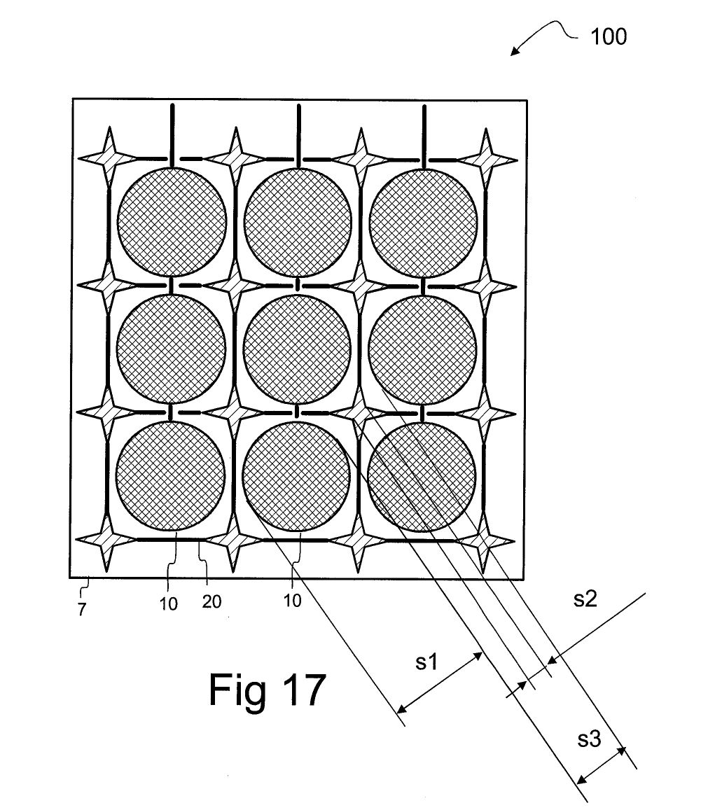

Yet, referring to FIG. 17, the sensor 100 may comprise e.g. an array of substantially circular signal electrodes 10 having e.g. star-shaped base electrode areas between them. In this example the distance s3 between the diagonally adjacent signal electrodes is greater than 20% of the width s1 of the signal electrodes. Thus, the blind spot between signal electrodes is rather large. However, because the width s2 of the base electrode structure between the signal electrodes is still smaller than or equal to 20% (preferably smaller than or equal to 10%) of the width s1 of the signal electrode 10, the varying voltage is still effectively coupled to the body BOD1.

The surface area of that part of the base electrode structure 20 which is between the adjacent first and second signal electrodes may be smaller than 20% of the surface area of the first signal electrode, and preferably smaller than or equal to 10% of the surface area of the first signal electrode.

The terminals of the conductors W are formed by cutting the sensor web across its longitudinal direction to a desired length, and thus the ends of the conductors are exposed and are ready for forming an electrical contact. The attachment method of the sensor web in contact can be, but is not limited to, crimp connector, spring connector, welded contact, soldered contact, isotropic or anisotropic adhesive contact. However, a standard connector used in common electronic applications (e.g. Crimpflex®, Nicomatic SA, France) can be attached to the ends of the conductors W.

The surface area of a conductor W connected to a signal electrode 10a, 10b, 20 may be smaller than 10% of the surface area of said electrode, in order to guarantee spatial resolution and in order to minimize power consumption.

The sensor 100 may comprise at least six electrically separate signal electrodes, which together cover at least 70% of the surface area of the substrate 7.

The sensor 100 according to the invention may be used e.g. to monitor the presence and/or movements of people in private houses, banks or factories in order to implement an anti-theft alarm system. A network of sensors 100 may be used to monitor the presence and/or movements of people in department stores e.g. in order to optimize layout of the shelves. The sensor may be used e.g. in hospitals or old people's homes to detect patient activity and their vital functions. The sensor may be used in prisons to monitor forbidden areas. The sensor may be used for detecting movement of other large conductive bodies, such as wheelchairs or aluminum ladders. The sensor may be used for detecting movement of animals.

The sensor 100 may be installed e.g. on or in a floor structure.

The substrate 7 may comprise plastic material, or fibrous material in the form of a nonwoven fabric, fabric, paper, or board. Suitable plastics are, for example, plastics comprising polyethylene terephtalate (PET), polypropylene (PP), or polyethylene (PE). The substrate is preferably substantially flexible in order to conform to other surfaces on which it is placed. Besides one layer structure, the substrate can comprise more layers attached to each other. The substrate may comprise layers that are laminated to each other, extruded layers, coated or printed layers, or mixtures of these. Usually, there is a protective layer on the surface of the substrate so that the protective layer covers the electrically conductive areas and the conductors. The protective layer may consist of any flexible material, for example paper, board, or plastic, such as PET, PP, or PE. The protective layer may be in the form of a nonwoven, a fabric, or a foil. A protective dielectric coating, for example an acrylic based coating, is possible.

The electrically conductive areas comprise electrically conductive material, and the electrically conductive areas can be, for example, but are not limited to, printed layers, coated layers, evaporated layers, electrodeposited layers, sputtered layers, laminated foils, etched layers, foils or fibrous layers. The electrically conductive area may comprise conductive carbon, metallic layers, metallic particles, or fibers, or electrically conductive polymers, such as polyacetylene, polyaniline, or polypyrrole. Metals that are used for forming the electrically conductive areas include for example aluminum, copper and silver. Electrically conductive carbon may be mixed in a medium in order to manufacture an ink or a coating. When a transparent sensor product is desired, electrically conductive materials, such as ITO (indium tin oxide), PEDOT (poly-(3,4-ethylenedioxythiophene)), or carbon nanotubes, can be used. For example, carbon nanotubes can be used in coatings which comprise the nanotubes and polymers. The same electrically conductive materials also apply to the conductors. Suitable techniques for forming the electrically conductive areas include, for example, etching or screen printing (flat bed or rotation), gravure, offset, flexography, inkjet printing, electrostatography, electroplating, and chemical plating.

E.g. the following manufacturing method may be used. A metal foil, such as an aluminum foil, is laminated on a release web. The electrically conductive areas and the conductors are die-cut off the metal foil, and the remaining waste matrix is wound onto a roll. After that, a first protective film is laminated on the electrically conductive areas and the conductors. Next, the release web is removed and a backing film is laminated to replace the release web.

Benefits of the above-mentioned manufacturing method include:
the raw material is cheaper,
the manufacturing method is cheaper compared to e.g. etching,
the manufacturing method requires only one production line, and
the resulting sensor web is thinner; the thickness of the sensor web may be less than 50 μm.

Electrically conductive areas and conductors may be die-cut from a metal foil, and they may be laminated between two substrates, i.e. between two superimposed webs.

Electrically conductive areas and their conductors may be located in one layer, and optional RF loops and their conductors may be located in another layer. In principle, it is possible to use different techniques, e.g. etching, printing, or die-cutting, in the same product. For example, the electrically conductive areas may be die-cut from a metal foil, but their conductors may be etched. The electrically conductive areas and their conductors may be connected to each other through vias.

The monitoring unit 50 may be arranged to provide a signal which depends on the capacitance formed by the electrodes 10a, 20. Said signal may be provided e.g. by a time constant measurement, by measuring an impedance by using the varying voltage V₁₂, by connecting the electrodes as a part of a tuned oscillation circuit, or by comparing said unknown capacitance of the electrodes with a known capacitance.

The time constant may be determined e.g. by charging the capacitor formed by the electrodes to a predetermined voltage, discharging said capacitor through a known resistor or inductor, and by measuring the rate of decrease of voltage of said capacitor.

The impedance may be measured by varying the voltage of said capacitor, by measuring the respective the current, and by determining the ratio of the change of current to the change of voltage.

The unknown capacitance of said capacitor may be determined by coupling them as a part of a resonating circuit comprising and inductance and said capacitor.

The unknown capacitance of said capacitor may be determined by charging or discharging the unknown capacitance by transferring a charge to it several times by means of a known capacitor unit a predetermined voltage is reached. The unknown capacitance may be determined based on the number of charge transfer cycles needed to reach the predetermined voltage.

### EXAMPLES

1. A sensor (100) for detecting presence of conductive objects (BOD1), said sensor (100) comprising a first signal electrode (10a), a second signal electrode (10b), and a base electrode structure (20) implemented in or on an electrically insulating substrate (7), wherein the distance (s3) between said first signal electrode (10a) and said second signal electrode (10b) is smaller than or equal to 0.2 times the width (s1) of said first signal electrode (10a), and wherein at least a part of said base electrode structure (20) is between said first signal electrode (10a) and said second signal electrode (10b), and wherein said base electrode structure surrounds at least 70% of the perimeter of said first signal electrode (10a).

2. A sensor (100) for detecting presence of conductive objects (BOD1), said sensor (100) comprising a first signal electrode (10a), a second signal electrode (10b), and a base electrode structure (20) implemented in or on an electrically insulating substrate (7), wherein the surface area of that part of said base electrode structure (20) which is between said first signal electrode (10a) and said second signal electrode (10b) is smaller than or equal to 20% of the area of said first signal electrode (10a), and wherein said base electrode structure surrounds at least 70% of the perimeter of said first signal electrode (10a).

3. The sensor (100) of example 1 or 2 wherein the surface area of said second signal electrode (10b) is in the range of 70% to 150% of the surface area of said first signal electrode (10b).

4. The sensor (100) according to any of the examples 1 to 3 wherein the surface area of said first signal electrode is in the range of 0.02 to 0.2 m².

5. The sensor (100) according to any of the examples 1 to 4 wherein the distance (s3) between said first signal electrode (10a) and said second signal electrode (10b) is in the range of 5 to 30 mm.

6. The sensor (100) according to any of the examples 1 to 5 wherein the width (s2) of a part of said base electrode structure (20) between said signal electrodes is in the range of 0.3 to 15 mm.

7. The sensor (100) according to any of the examples 1 to 6 wherein the surface area of said base electrode structure (20) is greater than or equal to the surface area of said first signal electrode (10a).

8. The sensor (100) according to any of the examples 1 to 7 wherein said signal electrodes (10a, 10b) and said base electrode structure (20) are substantially in the same plane, and conductive parts of said sensor (100) have been implemented on a flexible substrate (7).

9. A monitoring system for detecting a conductive body (BOD1), said system comprising a sensor (100) according to any of the examples 1 to 7, said system further comprising a monitoring unit (50), which is arranged to couple a varying voltage (V₁₂) between said first signal electrode (10a) and said base electrode structure (20), and which is arranged to provide a value which depends on the current of said signal electrode (10a) caused by said voltage variations.

10. The system of example 9 wherein said signal electrodes (10a, 10b) are covered with an electrically insulating layer (120), the thickness (d1) of said layer being greater than a gap (s4) between said first measuring electrode (10a) and said base electrode structure (20).

11. The system of example 9 or 10 wherein said sensor (100) has been installed on a floor and covered with a cover layer (120), wherein the thickness (d1) of the cover layer over the electrodes is greater than or equal to a gap (s(4) between the first signal electrode and the base electrode structure (20).

12. The system according to any of the examples 9 to 11 wherein said base electrode structure (20) connected to the earth (GND, 800).

13. The system according to any of the examples 9 to 12 wherein at least 90% of the power of the spectral components of said varying voltage (V₁₂) is within the frequency range of 20 kHz to 1 MHz.

14. The system according to any of the examples 9 to 13 wherein the second signal electrode 10b is switched to a high impedance state when the varying voltage (V₁₂) is coupled to said first signal electrode (10a).

15. The system according to any of the examples 9 to 14 comprising an array of monitoring units (50) coupled to an array of signal electrodes, and a data processor arranged to provide information on the location of said body (BOD1) based on a plurality of signals provided by said monitoring units (50).

16. The system according to any of the examples 9 to 15 system comprising an array of monitoring units (50) coupled to an array of signal electrodes, and a data processor arranged to provide information on the movement of a body (BOD1) based on a plurality of signals provided by said monitoring units (50).

17. A method of detecting a conductive body (BOD1) by using a sensor (100) according to any of the examples 1 to 8 or a system according to any of the examples 9 to 16, said method comprising coupling a varying voltage (V₁₂) between said first signal electrode (10a) and said base electrode structure (20), and determining a value which depends on the current of said signal electrode (10a) caused by said voltage variations.

18. The method of example 17 wherein the vertical dimension (z1) of said body (BOD1) is greater than or equal to the height (a1) and the width (s1) of said first signal electrode (10a).

19. A sensor web (77) comprising a plurality of sensors (100) according to any of the examples 1 to 8, wherein a substantially similar electrode pattern has been copied along the longitudinal dimension (direction SX) of said web (77) so that the electrode pattern has a longitudinal period.

20. The sensor web (77) of example 19 wherein conductors W of at least N successive periods cross a transverse line LIN2, wherein at least one conductor connected to a signal electrode which does not belong to said N periods terminates without crossing said transverse LIN2, N being an integer greater than or equal to three.

21. A sensor (100) obtainable by cutting the sensor web (77) of example 20 along two transverse lines (LIN1, LIN2).

22. The sensor (100) of example 21 wherein conductors (We3, Wd1, Wd2), which terminate without crossing said line LIN1 are not connected to any signal electrodes.

The word “comprising” is to be interpreted in the open-ended meaning, i.e. a sensor which comprises a first electrode and a second electrode may also comprise further electrodes and/or further parts.

For a person skilled in the art, it will be clear that modifications and variations of the devices and the method according to the present invention are perceivable. The particular embodiments and examples described above with reference to the accompanying drawings are illustrative only and not meant to limit the scope of the invention, which is defined by the appended claims.

1. A sensor (100) for detecting presence of conductive objects (BOD1), said sensor (100) comprising at least a first signal electrode (10a), a second signal electrode (10b), and a base electrode structure (20) implemented in or on an electrically insulating substrate (7), wherein the distance (s3) between said first signal electrode (10a) and said second signal electrode (1.0b) is smaller than or equal to 0.2 times the width (s1) of said first signal electrode (10a), and wherein at least a part of said base electrode structure (20) is between said first signal electrode (10a) and said second signal electrode (10b), and wherein said base electrode structure surrounds at least 70% of the perimeter of said first signal electrode (10a).

2. A monitoring system for detecting a conductive body (BOD1), said system comprising a sensor (100) according to claim 1, said system further comprising a monitoring unit (50), which is arranged to couple a varying voltage (V₁₂) between said first signal electrode (10a) and said base electrode structure (20), and which is arranged to provide a signal value which depends on the current of said signal electrode (10a) caused by said voltage variations.

3. A method of detecting a conductive body (BOD1) by using a sensor (100) according to claim 1, said method comprising coupling a varying voltage (V₁₂) between said first signal electrode (10a) and said base electrode structure (20), and determining a value which depends on the current of said signal electrode (10a) caused by said voltage variations.

4. A sensor web (77) comprising a plurality of sensors (100) according to claim 1, wherein a substantially similar electrode pattern has been copied along the longitudinal dimension (direction SX) of said web (77) so that the electrode pattern has a longitudinal period.

5. A method of detecting a conductive body (BOD1) by using a system according to claim 2, said method comprising coupling a varying voltage (V₁₂) between said first signal electrode (10a) and said base electrode structure (20), and determining a value which depends on the current of said signal electrode (10a) caused by said voltage variations.
